(19) United States
(12) Patent Application Publication
(10) Pub. No.: US 2003/0092280 A1
(43) Pub. Date: May 15, 2003

(54) Method for etching tungsten using NF3 and Cl2

(75) Inventors: Gene H. Lee, San Jose, CA (US); Nam-Hun Kim, Cupertino, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/039,333

(22) Filed: Nov. 9, 2001

(51) Int. Cl. H01L 21/302; H01L 21/461

(52) U.S. Cl. 438/720

(57) ABSTRACT

A method for etch a tungsten-containing layer (525) on a substrate (510) substantially anisotropically with good etching selectivity with respect to a hard mask layer, and without forming excessive passivating deposits on the etched features. In the method, the substrate (510) is placed in a plasma zone, and process gas mix comprising NF₃ and Cl₂is introduced into the plasma zone. A plasma is formed from the process gas mix to anisotropically etch the tungsten containing layer (525) to produce patterned tungsten features (535).

### INTRODUCTION

The present invention relates to the etching of tungsten-containing material on a substrate. More specifically, the present invention relates to main etch methods of etching tungsten and tungsten alloys with high selectivity to a hard mask disposed on the tungsten.

### BACKGROUND OF THE INVENTION

In integrated circuit fabrication, refractory metals (e.g., tungsten, tantalum, titanium, molybdenum) and their suicides, are used to form many useful structures, including gate electrodes, interconnect lines, and contact plugs.

In the case of transistor gate structures, the industry desires to use a tungsten layer in the gate because device makers are trying to reduce the overall delay time of the circuit. Since the delay time is proportional to the resistivity, the delay time can be reduced if the resistivity is reduced. Since tungsten has a lower resistivity than polysilicon, it is proposed that devices be made using a Si₃N₄/W/WN/polysilicon/gate oxide structure. The tungsten nitride (or WN) layer acts as a barrier layer between W and polysilicon, because without the intervening WN, diffusion between the tungsten and the polysilicon would form a WSi layer. The WSi is undesirable because it has a higher resistivity than W, and thus would be counterproductive to the goal of reducing the resistivity.

Refractory metals and their suicides are also used to form high density, high speed, electrically conductive interconnect lines and/or contact plugs for electrically connecting active semiconductor devices formed on silicon or gallium arsenide substrates. In a typical process, a blanket tungsten layer is deposited over an underlying titanium, titanium-nitride, titanium-tungsten, which serves as a barrier layer (or “adhesion” layer). This is followed by a masking step in which patterned etch resist (photoresist and/or hard mask) features are formed over the tungsten layer. To form interconnect lines on the substrate, an etch step is used to remove the tungsten material from the regions not covered by the etch resist features.

Tungsten layers can also be used for filling openings (or “vias”) to form electrically conducting contact plugs below interconnect wiring layers, by deposition of a blanket tungsten layer that fills the openings, followed by etching of the blanket tungsten layer to form the desired configuration of interconnect lines and/or plugs.

Tungsten is desirable for both interconnect lines and contact plugs for a number of reasons. Tungsten has a high melting temperature of about 3410 degrees C., compared to aluminum that melts at 660 degrees C., which allows high temperature processing of the substrate. Tungsten exhibits relatively low electromigration or diffusion when applied over a silicon layer. Tungsten reacts with silicon only at temperatures exceeding 600 to 700 degrees C., whereas aluminum reacts with silicon at substantially lower temperatures (˜250 degrees C.). Tungsten deposition generally provides very uniform filling of high aspect ratio contact plugs, very good step coverage, and relatively low tendency to form electrical discontinuities that cause shorts or breaks.

As the semiconductor industry strives to build cheaper and faster devices, it is compelled to increase surface density of the devices on the semiconductor substrate while trying to maintain the conductivity of the metal interconnects as high as possible. As a result, with each device generation the smallest in-plane dimensions of the interconnect lines (also known as critical dimension or CD) are scaled down faster than the stacked metal layer thickness. At present, it is not uncommon to see interconnect lines 25 with the aspect ratio (which is the ratio of line height to its width) as high as two or three, and in the near future it may be as high as four. This poses especially stringent requirements on the processes used to etch these interconnect lines.

To fabricate such high aspect ratio interconnect lines it is necessary to perform highly anisotropic etching (as opposed to isotropic etching) of a metal-containing layer. FIG. 1 illustrates isotropic etching in which the etch rates in the direction parallel to the plane of the substrate 20 (into the side-wall) are substantially the same as the etch rates that proceed vertically (so that the distance a is the same as the distance b). This results in undercutting below the etch resist mask layer 30 that makes it difficult to etch spaces between the interconnect lines 25 that are narrower than twice the thickness of the etched depth, which means that only an aspect ratio (for the line spacing) of less than 0.5 can be achieved.

Referring to FIGS. 2-4, anisotropic etching processes are illustrated. FIG. 2 shows etching still proceeding into the sidewall but at a slower rate than etching in the vertical direction (a<b). The most desirable case of highly anisotropic etching is shown in FIG. 3, when etch rate in the direction parallel to the substrate 20 is exactly zero (a=0). FIG. 4 illustrates the case of highly anisotropic etch, when the bottom of an etched line is wider than its top, or in other words etch rate in the parallel direction is negative (a<0) and the profile angle a is more than 90 degrees. Though, all of these situations are possible while etching metals and alloys such as aluminum, copper, tungsten, titanium, tantalum, etc., the shape of the etched feature shown in FIG. 3 is the most desirable because it allows, at least in principle, a spacing between metal interconnect lines 25 of very high aspect ratios.

One way of achieving highly anisotropic etch is performed in a plasma etching apparatus. Plasma provides anisotropic etching because it possesses a highly anisotropic source of energetic ions. The ions present in the plasma are accelerated towards the substrate in the plasma sheath, and collisions of these ions with the surfaces parallel to the substrate provide additional energy (in excess of the thermal energy) that accelerates certain surface reactions. Unlike the ions, neutral species are not directional and, therefore collide with all the surfaces exposed to plasma. The thermal energy available from the surface and the neutral plasma species does not differentiate between surface orientations. Thus, if the set of surface reactions responsible for etching is not sensitive to the additional energy provided by the ions, as is the case for etching many metals with halogens (e.g., etching aluminum with chlorine or etching tungsten with fluorine (in the absence of contaminants)), isotropic etching is obtained. When the etching reaction has an activation energy that is higher than the thermal energy, it will take place only on those substrate surfaces that are subjected to the energetic plasma ion bombardment, and etching proceeds essentially in the direction perpendicular to the substrate.

To facilitate etching, the etching process gas mix includes at least one reactive etching gas that easily reacts with the material being etched to form volatile gaseous byproducts that are removed from the reactor with a vacuum pump. Optionally, the etching process gas mix also includes a gas inhibitor or passivator that forms an inhibitor layer deposited on sidewalls of the freshly etched metal features (for example, FIG. 3, layer 37.) The inhibitor layer partially or completely blocks the access of the etching gas (usually halogen) to the sidewall to provide anisotropic etch. At the same time, it does not accumulate on the surfaces subjected to the ion bombardment, as it is being sputtered or etched off with the ion assistance, thus allowing the etching process to proceed. Thus the gas inhibitor has two somewhat conflicting requirements, it has to be deposited easily on the sidewalls and form a dense layer impermeable to etch gas, and it has to be easily etchable under ion bombardment in the atmosphere of the same etch gas. These requirements make finding a good inhibitor gas difficult, and at the same time, it is essential for successful profile etching of metal interconnect lines.

Processes for etching tungsten-containing layers use a plasma that includes halogen-containing gases, often fluorinated gases such as CF₄, SF₆, CBrF₃, and NF. The plasma often additionally includes an inhibitor gas, such as CBr, NF₃, or CHF₃, that forms thick passivating deposits on the sidewalls of the etched features to reduce horizontal etching For further details, refer to the description in J. Vac. Sci. Technol. B, page 3272 (1985). Unfortunately, such methods often result in etched features which have wider dimensions at the base due to the increased thickness of the passivating film that forms on the freshly etched sidewalls of the features as the etch process proceeds to completion.

Another method of etching tungsten containing layers uses gas mixtures of SF₆/CBrF₃ or SF₆/CHF₃ to reduce undercutting, but these mixtures nonetheless yield isotropic profiles with substantial undercutting at the base of the etched feature. For a discussion of this phenomenon, refer to Tennant, et al., J. Vac. Sci. Technol. B, page 71836 (1989).

According to yet another etching method, the tungsten film is etched using (i) an etchant gas such Cl₂ or SF₆; and (ii) a passivating film forming halogen gas containing C or Si (e.g., CCl₄, CF₄, CHF₃, CHCl₃, SiF₄, or SiCl₄) to form deposits on the surface of the substrate during etching. For additional details, refer to the description in U.S. Pat. No. 4,992,136 to Tachi et al. Unfortunately, this method tends to provide tapered angles for the sidewalls of the etched features because it is difficult to precisely control the ratio of the etchant gas to the film forming gas during the etching process, particularly towards the completion of the etching process when a high concentration of volatile passivating polymeric species is formed in the etch chamber.

Still another method of etching tungsten containing layers uses gas mixtures of SF₆/CHF₃ and N₂/CHF₃. Details of this method are available in the disclosure of U.S. Pat. No. 5,866,483 to Shiau et al. This method solves many of the difficulties outlined above and is incorporated by reference herein, in its entirety. However, the method of the '483 Patent does not address selective etching requirements of the situation where the photoresist material being used is a “hard mask”. Hard mask is an industry term referring to a special family of materials in the context of their use as an etch mask layer.

Conventional etching processes also often fail to maintain the critical dimensions of the etched features, which are predefined and desirable dimensions of the etched features, used to determine the electrical properties of the etched features, in the design of integrated circuits. The critical dimensions are those dimensions that have a significant effect on the electrical properties of the etched features. In modern integrated circuits, the line widths of interconnect lines, the diameters of contact plugs, and the widths of gates are becoming increasingly smaller to levels below 0.25 microns, to accommodate higher circuit densities. Because the electrical resistance of these features is proportional to the cross-sectional area of the etched features, it is important to maintain consistent and uniform dimensions without variations across an etched feature or between different etched features. Tapering cross-sections, cross-sectional profiles that vary as a function of the spacing between the features, or other variations in the profile of the features is no longer acceptable in modem integrated circuits. The critical dimensions are typically measured as a ratio or difference between the width Wᵣ of the resist features and the width Wₑ of the resultant etched features. The closer the width of the etched feature to that of the resist feature the more predictable and reliable are the electrical properties of the etched feature.

In order to improve upon attainable critical dimensions, so called “hard mask” photoresist layers were developed. Hard masks are commonly formed from silicon oxynitride (SiOₓN_{y}), silicone oxime (e.g. Si_{(1-x+y+z)}NₓO_{y}:H_{z}) and silicon nitride (Si₃N₄). Use of such hard masks are described in U.S. Pat. No. 6,121,123 to Lyons et al. and U.S. Pat. No. 6,171,973 to Schiavone et al. An important feature of hard mask etch resist layers is that they are substantially thinner compared to photoresist. This thinness results in improved patterning.

Using FIG. 5 as illustrative, etch resist layer 530 is a patterned hard mask that has its patterning photo resist layer previously removed. During etching of the tungsten containing layer 525, an etching scheme is desired that has a high selectivity of tungsten over the etch resist layer 530. The higher the selectivity, the closer the etching will approach the ideal anisotropic etching profile. More importantly, the higher the selectivity, the less thick the hard mask needs to be to survive the entire tungsten etch process with also being etched away entirely. Being able to deposit a thinner hard mask yields the advantage of speeding up overall process time.

Etch with high selectivity between tungsten containing layer 525 and hard mask etch resist layer 530 has not existed in the prior art. The best tungsten to hard mask selectivity available has been about 1:1. Although it may be possible to improve selectivity somewhat by using higher processing temperature, the use of high temperatures is not likely a satisfactory solution because of the need to keep processing temperatures at levels low enough to avoid promoting diffusion of dopants in the devices.

A high degree of anisotropic etching is obtained when dissociated species in the etchant gas combine to deposit passivating layers on the sidewalls 540 of freshly etched features 535 to limit further etching of the sidewalls 540. Anisotropic etching is also obtained by the highly directional kinetic energy of the charged species in the etchant plasma (in the electric field perpendicular to the substrate 510), which causes the plasma species to energetically impinge upon and remove substrate material in the vertical etching direction. However, different materials are sputter etched by highly energized plasma species at the high etch rates to provide little or no control over etching selectivity. For these reasons, it is difficult to obtain highly anisotropic etching in combination with high etching selectivity ratios for etching tungsten-containing material relative to hard mask materials.

It is particularly desirable have high etching selectivity ratio for tungsten containing structures having a partially convoluted topography, where portions of the tungsten containing layer 525 are thicker across the substrate 510. The etch process according to the present invention is useful as a main etch step that is to be terminated before the thinner portions of the tungsten containing layer 525 are etched through and etching of the underlying silicon dioxide layer would begin. Higher selectivity is also desirable because if the mask loss during etching is reduced, then it becomes possible to reduce the thickness of the hard mask. By reducing the hard mask thickness, the amount of time spent building up the hard mask can be reduced, thus improving overall device throughput.

Thus, it is desirable to have a process for etching tungsten-containing layers that exhibits anisotropic etching and provides etched features having substantially straight sidewalls. It is also desirable for the etching process to have a high selectivity between a tungsten-containing layer and a hard mask etch resist layer overlying the tungsten. It is further desirable for the etching process to provide etched features having consistent and reproducible critical dimensions. Additionally, it is desirable for the etching process to exhibit reduced and more controllable formation of passivating film deposits on the sidewalls of the etched features. It is further desirable for the etching process to have a large processing window tolerant of process fluctuations and provide a high process throughput.

### SUMMARY OF THE INVENTION

The present invention provides highly anisotropic etching of tungsten containing layers on a substrate to provide low loss of critical dimensions and prevent excessive deposition of thick passivating films on the etched features.

One aspect of the present invention is anisotropic etch of tungsten film while maintaining high etch selectivity with respect to silicon nitride (S₃N₄) hard mask. Results have been demonstrated according to the novel chemistry based on a mix of NF₃ and Cl₂ that are superior to prior art fluorine-based chemistries.

One way of practicing the method is effected by placing a substrate to be processed into a plasma zone, and introducing a process gas comprising NF₃ and Cl₂ into the plasma zone. A plasma generated from the process gas etches a tungsten-containing layer on the substrate substantially anisotropically and without forming excessive passivating deposits on the substrate. Importantly, any S₃N₄ hard mask overlying the tungsten-containing layer is selectively etched at a rate that is substantially less that the rate of etch of the tungsten-containing layer.

According to one approach, the volumetric flow ratio of NF₃:Cl₂ is selected so that the tungsten containing layer is etched to provide etched features having sidewalls that form angles of at least about 88 degrees with a surface of the substrate. Preferably, the volumetric flow ratio of NF₃:Cl₂ is from about 1:1 to about 1:2.5 and more preferably from about 1:1.3 to 1:2. According to an alternate approach that provides less passivation, the chlorine flow is de-emphasized so that the volumetric flow ratio of NF₃:Cl₂ is from about 1:1 to about 2:1 and more preferably from about 1.3:1 to 2:1.

Additional objects and advantages of the present invention will be apparent in the following detailed description read in conjunction with the accompanying drawing figures.

### BRIEF DESCRIPTION OF THE DRAWINGS

FIG. 1 illustrates a sectional view of isotropically etched features.

FIG. 2 illustrates a sectional view of moderately anisotropically etched features.

FIG. 3 illustrates a sectional view of anisotropically etched features having ideal vertical sidewalls.

FIG. 4 illustrates a sectional view of highly anisotropically etched features having a positive profile.

FIG. 5 illustrates a partial sectional view of a substrate having a tungsten layer and a patterned resist layer thereon.

FIG. 6 illustrates a partial sectional view of the substrate of FIG. 5 after etching of the tungsten layer showing substantially anisotropically etched features.

FIG. 7 illustrates a schematic view in vertical cross-section of a process chamber suitable for practicing the etching process of the present invention.

FIG. 8 illustrates a cross-sectional perspective view (from below) of a substrate having a tungsten layer etched using one embodiment of the present invention.

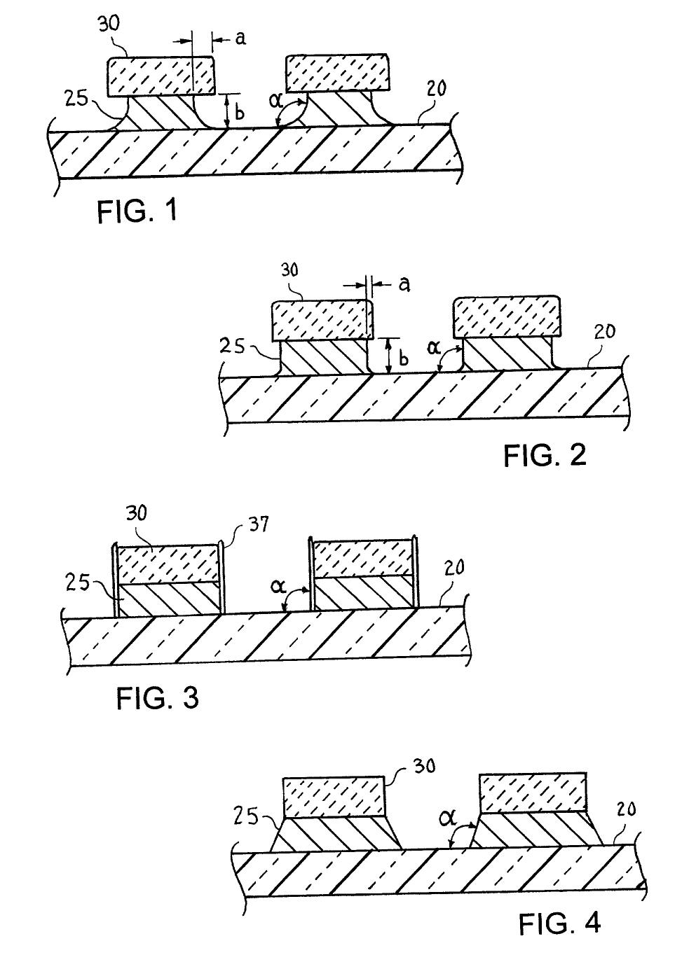

### DETAILED DESCRIPTION OF THE EXEMPLARY EMBODIMENTS

Plasma etch according to the present invention yields an anisotropic etch of tungsten film while maintaining high etch selectivity with respect to silicon nitride (S₃N₄) hard mask. Results have been demonstrated according to the novel chemistry based on a mix of NF₃ and Cl₂ of a selectivity ratio of 2.5:1 for tungsten with respect to S₃N₄. This is much better that the 1:1 (at best) results obtainable via prior art fluorine-based etch chemistries.

It is possible according to this etch process to etch tungsten to a vertical etch profile with no CD gain or re-entrant profile, while maintaining high selectivity to nitride mask. With NF₃/Cl₂ based chemistry, selectivity to Si₃N₄ mask of better that >2.5:1 is consistently provided, and selectivity of 5:1 is believed to be possible. Using other fluorine-based chemistries at low temperature the W:Si₃N₄ selectivity is <1:1.

Superior etch selectivity results are also obtained with NF₃/Cl₂ in the case where SiON (silicon oxynitride) mask is used.

A proper ratio of NF₃ gas to Cl₂ gas provides the necessary reactants to remove the tungsten (or tungsten alloy) film while providing passivation on the tungsten sidewall to prevent lateral etch. The patterned tungsten film is useful as a conducting material for transistor gates and DRAM bit-line applications, among other things.

One embodiment of the present invention etching process is useful for highly anisotropic etching of a tungsten layer formed on a substrate and masked with silicon nitride, while leaving reduced amounts of passivating deposits and with a good etch rate that is very selective with respect to the mask.

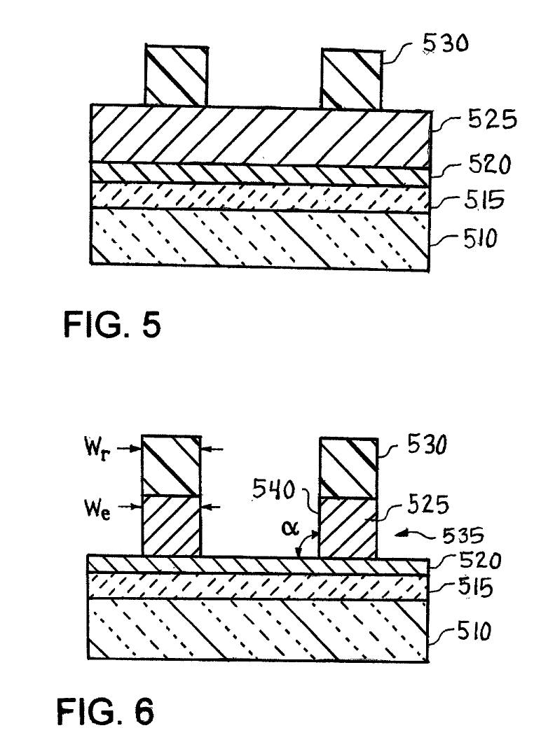

Referring to FIG. 5, a schematic view of wafer prior to etch processing according to an embodiment of the present invention is illustrated. An etch resist hard mask layer 530 is patterned onto a layer that contains tungsten 525, which is disposed on a substrate 510. The substrate 510 may be made of any material, such as glass, ceramic, metal, polymer, or a semiconductor substrate, for example a wafer of silicon or gallium arsenide. Optionally, other layers are also present. Other desired layers may include a dielectric layer 515 such as doped or undoped silicon dioxide, silicon nitride, BPSG, or PSG (which is typically about 100 to 3000 Å thick), formed on the substrate 510.

To obtain the pre-etch layer configuration as shown in FIG. 5, the substrate 510 is de-scummed to remove the native oxide layer on the silicon containing surfaces. This is done typically using an O₂ plasma. A thin barrier or adhesion layer 520 may also be deposited on the substrate 510. The adhesion layer 520 may be, for example, a layer of titanium (Ti), titanium tungsten (Ti—W), or titanium nitride (TiN) having a thickness of 100 to 1000 Å. Common methods for depositing the tungsten-containing layer 525 are by sputtering from a tungsten target, or by chemical vapor deposition from tungsten source gases, such as tungsten hexafluoride (WF₆). Additionally, for example, a chemical vapor deposition process for depositing WSiₓ films via plasma enhanced chemical vapor deposition of tungsten hexafluoride and dichlorosilane is described in detail in commonly-assigned U.S. Pat. No. 5,500,249 to Telford et al., which is incorporated by reference herein. The tungsten-containing layer 525 typically has a thickness of about 500 Å to about 10,000 Å, and is commonly deposited by a low temperature RF biased sputtering process.

The hard mask patterned layer 530 is typically patterned via conventional photolithographic methods using a patterned photoresist patterned layer (not shown) covering the hard mask layer 530. It may also be patterned via process that utilizes electron beam lithography. Electron beam lithography systems are available from companies such as ETEC, DuPont de Nemours Chemical Company, and Lucent Technologies. The etch resist layer 530 has features dimensioned according to the critical dimensions of the features desired to be etched in the tungsten containing layer. In this step, a layer of hard mask etch resist 530, such as silicon nitride, is applied on the tungsten containing layer 525 to a thickness of about 0.4 to about 1.3 microns.

Referring to FIG. 6, after the etching process of exposure to a plasma of NF₃ mixed with Cl₂, the resist mask features 530 result in formation of the etched, tungsten-containing features 535.

The tungsten-containing layer 525 is etched in a process chamber, such as for example, a decoupled plasma source (DPS) chamber that is commercially available from Applied Materials Inc., Santa Clara, Calif. For details concerning such plasma processing chambers, refer to U.S. Pat. No. 5,777,289 to Hanawa et al. and U.S. Pat. No. 5,753,044 to Hanawa et al., both of which are incorporated by reference herein. Of course, practice of etch processes according to the present invention are not limited to any particular processing platform. Etching process embodying to the present invention can be used to simultaneously etch multiple substrates, and can be used for manufacturing processes other than semiconductor fabrication.

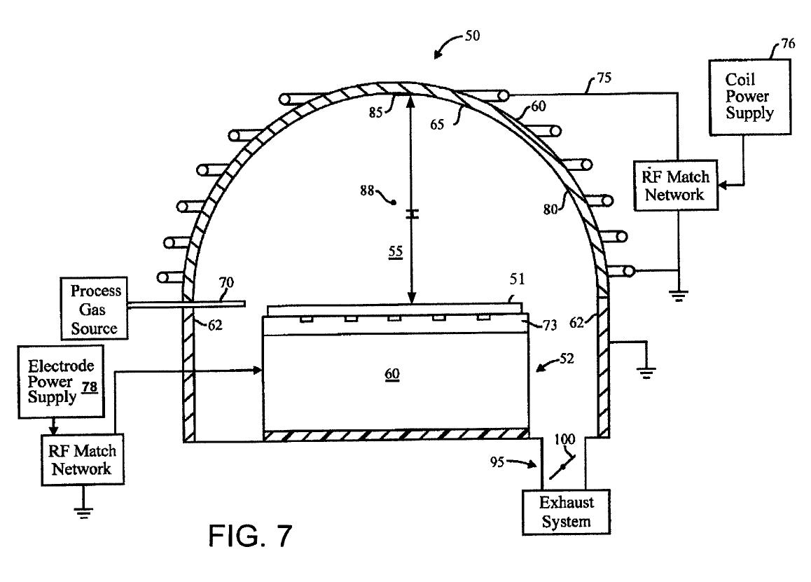

Referring to FIG. 7, according to an exemplary embodiment, an etch process step is effected by evacuating the chamber 50 to a low pressure (e.g., less than about 1 Torr) and a wafer 51 is placed on a support 52 within a plasma zone 55 in the chamber 50. At least a portion of the support 52 is electrically conductive and serves as a cathode electrode 60. The cathode electrode 60, in conjunction with sidewalls of the chamber 50 which are electrically grounded to serve as an anode electrode 65, form process electrodes in the plasma zone 55 that form a capacitive electric field that generates or energizes the plasma in the chamber. The wafer 51 is held in place during the etching process using a mechanical or electrostatic chuck with grooves in which a coolant gas, such as helium, is held to control the temperature of the wafer stack 51.

The wafer 51 in the chamber is typically maintained at a temperature of about 50 degrees C., but the temperature may range anywhere from 10 degrees C. to 80 degrees C. The wafer is cooled by flowing helium gas below the substrate 10 at a pressure of about 1 to 10 Torr (nominally 8 Torr). However, maintaining a consistent, cool wafer temperature has been discovered not to be an important consideration for the process according to the present invention. For many prior art etch processes, lower substrate temperatures provide increased control of the cross-sectional profile of the etch features by reducing vaporization of the passivating film formed on the etch features. The etch process according to the present invention has been found to be relatively insensitive to temperature. For example, in one test run, the cooling helium was turned off and the wafer temperature permitted to rise to 200 degrees C., resulting in no meaningful difference in the resulting etch performance. This relative insensitivity to temperature appears to be an additional advantage over prior art etch chemistries.

The process is sensitive to pressure changes. Process gas is introduced into the chamber 50 through a gas distributor 70 peripherally disposed about the wafer stack 51, and the pressure in the chamber is regulated to about 1 to about 1000 mTorr, more typically from 3 to 30 mTorr, and preferably about 15 mTorr. A plasma is formed from the process gas using a plasma generator that couples an energetic electromagnetic field into the plasma zone 55, such as an inductive, capacitive, or microwave field. Preferably, the plasma generator comprises both an inductive and a capacitive plasma source. The inductor coil 75 adjacent to the process chamber 50 that forms an inductive electric field in the chamber when powered by a coil power supply 76 operated using an RF current, nominally at a frequency of about 2 MHz. It has been determined that processes according to the present invention are not very sensitive to the amount of power applied to generate and maintain the plasma. Inductive (source) power is in the range of 100-1000 W and capacitive (bias) power is in the range of 20-200 W. The profile and selectivity of etch may be optimized by making power adjustments, similarly to fine-tuning of other dry etch processes.

To achieve an etch step that takes a masked tungsten-containing layer 525 as shown in FIG. 5 and leaves etched tungsten-containing features 535 as shown in FIG. 6, the present invention calls for the use of a plasma etch gas mix of nitrogen trifluoride (NF₃) and chlorine (Cl₂) to perform a main etch. It has been discovered that the degree of selectivity of etch, between hard mask resist 530 and the tungsten-containing layer 525, is sensitive to the ratio of NF₃ gas to the Cl₂ gas.

The nitrogen contributed by the NF₃ provides selectivity to the nitride mask. The F³¹ ions contributed by the NF₃ act as the primary etch agent by combining with tungsten atoms from the tungsten-containing layer 525 to form WF, which is highly volatile and, thus, is easily pumped out of the vacuum chamber.

Some of the Cl⁻ ions contributed by the Cl₂ combine with tungsten atoms from the tungsten-containing layer 525 to form WCl, which is non-volatile at low temperature. The non-volatile WCl tends to deposit on the vertical walls 540 being etched to act as a passivator film. It is this passivator film that ensures the near-ideal verticality of the walls 540 of the etched features 535.

Gas chemistry according to the present provides excellent control of the critical dimensions of the etched features and highly anisotropic etching of the features. If needed, passivating gases can be added to the main etch process gases. Acceptable passivating gases include for example CHF₃ and N₂. Passivating gases in the plasma form passivating films that protect the etched sidewalls 540 of the features 535, and reduce isotropic etching, tapering, and undercutting of the etched features 535. At the same time, the thickness of the passivating film is controlled to prevent formation of excessively thick passivating films on the etched tungsten features. It is difficult to measure the thickness of the passivating polymeric film formed on the etched features, other than measuring CD bias. However, it has been found that excessively thick passivating films provide etched features having a tapered profile that is thicker at the bottom and thinner at the top.

The composition and volumetric flow ratios of different constituents of the main etch process gas are also selected to provide anisotropically etched features 535 having sidewalls 540 with smooth surfaces that form angles (alpha) of at least about 88 degrees with a plane of the wafer 551, and more preferable angles from about 89 degrees to about 90 degrees. Anisotropically etched features 535 result when the tungsten containing layers are etched substantially vertically to provide features having straight sidewalls 540. Excessive etching at the sidewalls 540 of the etched features 535 results in undesirable inwardly or outwardly sloped walls.

For a process chamber the size of the DPS chamber suggested herein, the flow rate of NF₃ is preferably from about 20 to about 60 sccm and the flow rate of Cl₂ is from about 20 to about 60 sccm. The total flow rate of the main etch process gas for such a chamber size is from about 60 to 200 sccm. It should be understood, however, that process gas flow rates are dependent upon the size of the process chamber and flow rates for different sized chambers that provide the equivalent function and/or etching properties are encompassed within the scope of the present invention.

An over etch step is performed to finish off the last bit of the tungsten-containing layer 525. Typically the over etch process is carried out in the same DPS chamber, but with gases selected for over etching. The tungsten etch is completed in an over etch step that uses a different chemistry that is highly selective to etching of tungsten with respect to the underlying layer. Thus, in the over etch step the remaining thicker portions of the tungsten-containing layer 525 are still being etched without etching away the underlying layer where the tungsten-containing layer was thinnest.

The critical dimensions (“CD”) are the predefined and desirable dimensions of the etched features, which are used to determine the electrical properties of the etched features, in the design of integrated circuits. The critical dimensions are dimensions of etched features that can have a significant effect on its electrical properties. For example, the electrical resistance of metal interconnect lines is proportional to the cross-sectional area of the etched features, particularly, the height and width of the etched features. As the dimensions of etched features are diminished due to advances in etching technology, the cross-sectional area of the interconnect lines becomes a critical dimension that should be maintained as close to the desired dimensions as possible to provide the required electrical resistance levels. Thus, tapering cross-sections, cross-sectional profiles that vary as a function of the spacing between the features, or other variations in the profile of the features is no longer acceptable in modern integrated circuits.

Critical dimension measurements are typically made using cross-sectional scanning electron micrographs of the substrate before and after etching. The average width (Wᵣ) of resist features 530 formed on the blanket tungsten layer 525 is measured prior to etching; and after etching a second width (Wₑ) of the etched features 535 is measured. The critical dimension loss is the difference between the two dimensions of Wᵣ−Wₑ. The % critical dimension loss is [(Wᵣ−Wₑ)/Wᵣ]×100%. The minimum critical dimension is the average value of the smallest width across the cross-sections of the etched features 535. It is further desirable to provide a percent critical dimension loss of less than 4% and more preferably less than 2%.

In certain processes, it may be desirable to add argon to the process gases to promote the stability of the plasma. This is sometimes desirable for etching elemental tungsten layers or substrates, which cause plasma instabilities in various etch gases. By plasma instability, it is meant a sporadic or intermittent formation of bright and dark plasma glow regions that are caused by unstable electron and ion levels in the plasma. It is believed that the argon gas promotes plasma stability by providing additional energetic species that strike upon, ionize, and/or dissociate the process gas molecules. However, the argon gas addition may not be desirable when the plasma is sufficiently stable without the additional inert gas.

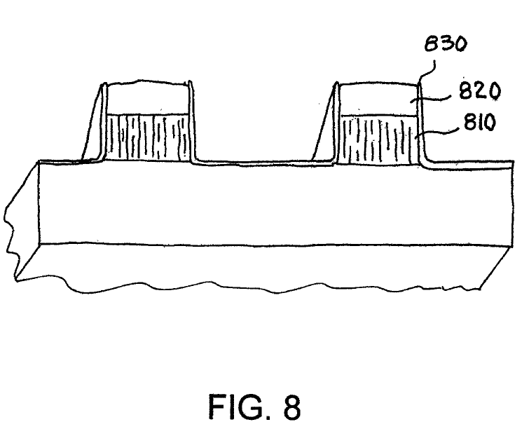

Referring to FIG. 8, the unexpected results obtained using the process gas composition of the present invention are demonstrated. This figure represents a cross-sectional perspective view (from below) of a vertically sectioned post-etch wafer with features etched in the tungsten layer on the substrate. In this example, an 8-inch silicon wafer was used as the substrate. The etched tungsten features 810, with the remaining hard mask 820 sitting on top of them have been etched out of the tungsten containing-layer. Small spikes 830 of passivation coatings can be visibly discerned sticking up at opposite edges of the hard mask 820.

The exemplary etch run that produced the result illustrated in FIG. 8 was effected by placing a wafer into a DPS plasma chamber. After the process gas was introduced into the chamber, the chamber pressure was maintained at 15 mTorr. The substrate was maintained at a temperature of about 50 degrees C. by flowing helium at a pressure of 8 Torr below the substrate. The source power level of the inductor coils was maintained at 400 Watts, and the bias power level of the process electrodes was maintained at 150 Watts. After main etch step, the residual tungsten-containing layer between the mask features was removed using an argon/chlorine over etch step to leave only the desired tungsten features.

In the exemplary etch run, results of which are shown in FIG. 8, the tungsten features were etched using the process gas mix embodied according to the present invention, namely 30 sccm NF₃ and 40 sccm Cl₂. The SEM micrographs show the unexpected highly anisotropic etching of the features provided by this process gas composition. In these examples, the features have substantially perpendicular sidewalls with substantially no tapering from the top of the feature to the bottom of the feature.

Table I shows the selectivity measured on cross-sections of the features etched in an exemplary etch run. Critical dimension measurements were made using cross-sectional views of scanning electron micrographs of the substrate before and after etching. The SEM micrographs were used to measure the average width (Wᵣ) of resist features 530 formed on the blanket tungsten layer prior to etching. After etching, a second width (Wₑ) of the etched features 535 was measured. The critical dimension loss was the difference Wᵣ−Wₑ and the % critical dimension loss was [(Wᵣ−Wₑ)/Wᵣ]×100%. The minimum critical dimension was measured as an average value of the smallest width across the cross-sections of the etched features 535.

TABLE I
Example Results

| Resist Layer | silicon nitride |
|---|---|
| Minimum Critical Dimension | 0.20 microns |
| % Critical Dimension Loss | |
| Profile Angle | |
| Selectivity of etchant (W:SiN) | 2.5 |

The critical dimension loss was less than 50 ∈. The % critical dimension loss was only 3%. Profile angles in the desired 88 to 90 degree range were obtained and the profiles comprise substantially uniformly vertical sidewalls. The sidewalls of the etched features were relatively smooth without serrated edges. These unexpected results of the anisotropic etching and excellent cross-sectional profile of the etched features demonstrate the advantage of the present process.

Although the present invention has been described in considerable detail with regard to the preferred version thereof, other versions are possible. For example, the plasma can be formed using a microwave plasma source, and various passivating and/or impurity gases can be used with the gas mixes described herein. Therefore, the appended claims should not be limited to the description of the preferred versions contained herein.

The present invention has been described in terms of preferred embodiments, however, it will be appreciated that various modifications and improvements may be made to the described embodiments without departing from the scope of the invention.

What is claimed is:

1. A method of anisotropically etching a layer containing tungsten, the layer being disposed on a substrate and having a patterned hard mask layer disposed thereon, the method comprising:
placing the substrate in a plasma zone;
introducing into the plasma zone a process gas mix comprising NF₃ and Cl₂; and
forming a plasma from the process gas mix to etch the tungsten containing layer substantially anisotropically and at an etch rate greater than the rate at which the hard mask layer is etched.

2. The method of claim 1, wherein tungsten containing layer is etched at an etch rate at least twice the rate at which the hard mask layer is etched.

3. The method of claim 1, wherein tungsten containing layer is etched at an etch rate that is about 2.5 greater than the rate at which the hard mask layer is etched.

4. The method of claim 1, wherein the process gas mix is introduced with a volumetric flow ratio of NF₃ and Cl₂ that is selected to provide etched features having a critical dimension loss of less than 4% and having sidewalls that form angles of at least about 88 degrees with a surface of the substrate.

5. The method of claim 1, wherein the gas mix is introduced with a volumetric flow ratio of NF₃:Cl₂ is in the range of from about 1:1 to about 1:2.5.

6. The method of claim 1, wherein the gas mix is introduced with a volumetric flow ratio of NF₃:Cl₂ is in the range of from about 1:1.3 to about 1:2

7. The method of claim 1, wherein the process gas mix consists essentially of NF₃ and Cl₂.

8. The method of claim 1, wherein the process gas mix further comprises a passivator gas.

9. The method of claim 1, wherein the hard mask layer comprises silicon nitride.

10. A method of etching a tungsten containing layer that is covered with a patterned hard mask layer and disposed on a substrate, using a process chamber that has process electrodes therein and an inductor coil adjacent to the process chamber, the method comprising:
placing the substrate on which the tungsten containing layer is disposed into the process chamber;
introducing into the process chamber, a process gas mix comprising NF₃ and Cl₂; and
ionizing the process gas mix to form plasma ions that energetically impinge on the tungsten containing layer and the hard mask layer by applying RF energy to the inductor coil and applying RF energy the process electrodes,
wherein the tungsten containing layer is substantially anisotropically etched at an etch rate greater than the rate at which the hard mask layer is etched.

11. The method of claim 10, wherein tungsten containing layer is etched at an etch rate at least twice the rate at which the hard mask layer is etched.

12. The method of claim 10, wherein tungsten containing layer is etched at an etch rate that is about 2.5 greater than the rate at which the hard mask layer is etched.

13. The method of claim 10, wherein the process gas mix is introduced with a volumetric flow ratio of NF₃ and Cl₂ that is selected to provide etched features having a critical dimension loss of less than 4% and having sidewalls that form angles of at least about 88 degrees with a surface of the substrate.

14. The method of claim 10, wherein the volumetric flow ratio of NF₃:Cl₂ is from about 1:1 to about 1:2.5.

15. The method of claim 10, wherein the volumetric flow ratio of NF₃:Cl₂ is from about 1:1.3 to about 1:2.

16. The method of claim 10, wherein the volumetric flow ratio of NF₃:Cl₂ is from about 1:1 to about 2:1.

17. The method of claim 10, wherein the volumetric flow ratio of NF₃:Cl₂ is from about 1.3:1 to about 2:1.

18. The method of claim 10, wherein the process gas mix consists essentially of NF₃ and Cl₂.

19. A method of etching a tungsten containing layer that is covered with a patterned hard mask layer and disposed on a substrate, using a process chamber that has process electrodes therein and an inductor coil adjacent to the process chamber, the method comprising:
placing the substrate on which the tungsten containing layer is disposed into the process chamber;
introducing into the process chamber, a main etch process gas mix comprising NF₃ and Cl₂;
ionizing the main etch process gas mix to form plasma ions that energetically impinge on the tungsten containing layer and the hard mask layer by applying RF energy to the inductor coil and applying RF energy the process electrodes, wherein the tungsten containing layer is substantially anisotropically etched at a main etch rate greater than the rate at which the hard mask layer is etched;
introducing into the process chamber, an over etch process gas mix comprising Ar and Cl₂; and
ionizing the over etch process gas mix to form plasma ions that energetically impinge on the tungsten containing layer and the hard mask layer by applying RF energy to the inductor coil and applying RF energy the process electrodes, wherein any remaining portion of the tungsten containing layer that is not masked by the hard mask layer is substantially anisotropically etched away.

20. The method of claim 19, wherein tungsten containing layer is etched at a main etch rate at least twice the rate at which the hard mask layer is etched.

21. The method of claim 19, wherein tungsten containing layer is etched at a main etch rate that is about 2.5 greater than the rate at which the hard mask layer is etched.
